(19) United States
(12) Patent Application Publication
(10) Pub. No.: US 2025/0374464 A1
(43) Pub. Date: Dec. 4, 2025

(54) GLASS AND ELECTRONIC DEVICE

(71) Applicant: Lenovo (Beijing) Limited, Beijing (CN)

(72) Inventors: Shaopeng PENG, Beijing (CN); Hailong WU, Beijing (CN); Nan LIN, Beijing (CN)

(21) Appl. No.: 19/222,678

(22) Filed: May 29, 2025

(30) Foreign Application Priority Data
May 31, 2024 (CN) 202410705184.5

(51) Int. Cl. H05K 5/03; H05K 5/02

(52) U.S. Cl. CPC H05K 5/03; H05K 5/0217

(57) ABSTRACT

Glass includes a first portion. The first portion includes a target texture structure and a light-transparent deformation object. The target texture structure is configured to reduce deformation stress of the glass. The light-transparent deformation object is arranged in a space of the target texture structure to cause a visual effect of the target texture structure to disappear.

### CROSS-REFERENCE TO RELATED APPLICATION

The present disclosure claims priority to Chinese Patent Application No. 202410705184.5, filed on May 31, 2024, the entire content of which is incorporated herein by reference.

### TECHNICAL FIELD

The present disclosure is related to the electronic technology field and, more particularly, to glass and an electronic device.

### BACKGROUND

Flexible display technology is widely used in the market. A flexible screen is bendable and has great potential in various commercial electronic products, such as a smartphone and a wearable device. However, in addition to improving the user experience, the reliability and protection of the flexible screen have become important technical challenges.

Often, when designing a flexible screen, a glass cover is arranged on the surface of the flexible screen to protect the screen from physical damage, such as scratches and impacts that may be encountered in daily use. However, by having the glass cover, the flexibility of the display screen is sacrificed to a certain degree, which limits the flexibility of product design and the user experience.

### SUMMARY

An aspect of the present disclosure provides glass, including a first portion. The first portion includes a target texture structure and a light-transparent deformation object. The target texture structure is configured to reduce deformation stress of the glass. The light-transparent deformation object is arranged in a space of the target texture structure to cause a visual effect of the target texture structure to disappear.

An aspect of the present disclosure provides an electronic device, including a deformation screen and glass. The deformation screen includes at least one first area. The glass covers the screen and includes at least one first portion. The first portion corresponds to the first area of the screen, and light emitted from the screen penetrates the glass. The first portion of the glass includes a target texture structure and a light-transparent deformation object arranged in a space of the target texture structure, and the target texture structure is configured to reduce deformation stress of the glass as the screen deforms.

### BRIEF DESCRIPTION OF THE DRAWINGS

FIG. 1 illustrates a schematic structural diagram of glass according to some embodiments of the present disclosure.

FIG. 2 illustrates a schematic structural diagram of another piece of glass according to some embodiments of the present disclosure.

FIG. 3 illustrates a schematic structural diagram of another piece of glass according to some embodiments of the present disclosure.

FIG. 4 illustrates a schematic structural diagram of another piece of glass according to some embodiments of the present disclosure.

FIG. 5 illustrates a schematic diagram showing a top view of glass according to some embodiments of the present disclosure.

FIG. 6 illustrates a schematic structural diagram of another piece of glass according to some embodiments of the present disclosure.

FIG. 7 illustrates a schematic diagram showing another top view of glass according to some embodiments of the present disclosure.

FIG. 8 illustrates a schematic diagram showing a top view of a target texture structure layout of glass according to some embodiments of the present disclosure.

FIG. 9 illustrates a schematic diagram showing another top view of a target texture structure layout of glass according to some embodiments of the present disclosure.

FIG. 10 illustrates a schematic diagram showing a top view of a target texture structure layout of glass according to some embodiments of the present disclosure.

FIG. 11 illustrates a schematic diagram showing a top view of a target texture structure layout of glass according to some embodiments of the present disclosure.

FIG. 12 illustrates a schematic diagram showing a top view of a target texture structure layout of glass according to some embodiments of the present disclosure.

FIG. 13 illustrates a schematic diagram showing a top view of a target texture structure layout of glass according to some embodiments of the present disclosure.

FIG. 14 illustrates a schematic structural diagram of another piece of glass according to some embodiments of the present disclosure.

FIG. 15 illustrates a schematic structural diagram of an electronic device according to some embodiments of the present disclosure.

FIG. 16 illustrates a schematic structural diagram of another electronic device according to some embodiments of the present disclosure.

FIG. 17 illustrates a schematic structural diagram of another electronic device according to some embodiments of the present disclosure.

FIG. 18 illustrates a schematic structural diagram of another electronic device according to some embodiments of the present disclosure.

FIG. 19 illustrates a schematic enlarged diagram of a shattered area when glass shatters due to an external violent collision after an anti-shatter layer is provided to a glass surface according to some embodiments of the present disclosure.

FIG. 20 illustrates a schematic structural diagram of another electronic device according to some embodiments of the present disclosure.

FIG. 21 illustrates a schematic structural diagram of another electronic device according to some embodiments of the present disclosure.

FIG. 22 illustrates a schematic diagram showing a certain angle between a first body and a second body of the electronic device in FIG. 21.

FIG. 23 illustrates a schematic structural diagram of another electronic device according to some embodiments of the present disclosure.

### DETAILED DESCRIPTION OF THE EMBODIMENTS

Embodiments of the present disclosure are described in detail below in conjunction with the accompanying drawings of embodiments of the present disclosure. The described embodiments are only some embodiments of the present disclosure, not all embodiments. Based on the embodiments of the present disclosure, all other embodiments obtained by those of ordinary skill in the art without creative effort shall fall within the scope of the present disclosure.

Various modifications and changes can be made to the present disclosure without departing from the spirit or scope of the present disclosure, which will be obvious to those skilled in the art. Therefore, the present disclosure intends to cover modifications and variations of the present disclosure that fall within the scope of the appended claims (the claimed technical solutions) and their equivalents. Embodiments of the present disclosure can be combined with each other when there is no contradiction.

To make the above objectives, features, and advantages of the present disclosure more comprehensible, the present disclosure will be further described in detail below with reference to the accompanying drawings and specific embodiments.

As described in the background section, a flexible screen often requires a layer of glass cover plate on the surface during design to resist physical damages such as scratches and impacts that may occur during daily use. However, providing the glass cover plate may sacrifice some of the flexible characteristics of the display screen, which limits the flexibility of product design and the user experience.

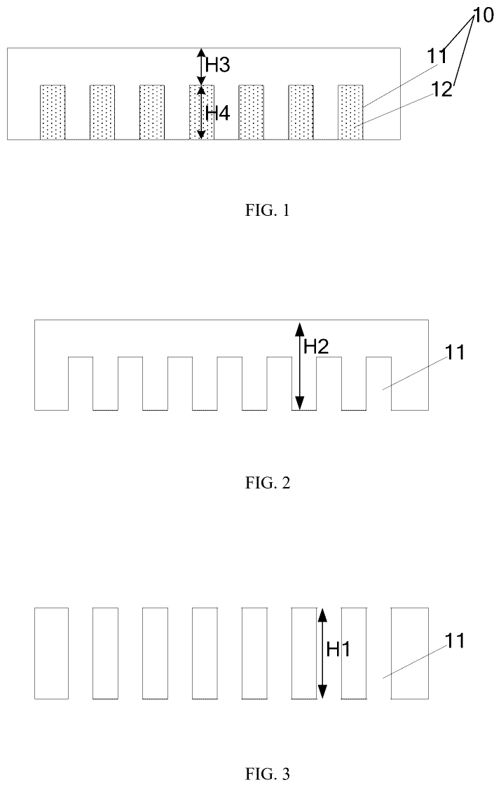

Based on this, embodiments of the present disclosure provide glass. As shown in FIG. 1 and FIG. 2, the glass includes a first portion 10. The first portion 10 includes a target texture structure 11 and a light-transparent deformation object 12.

The target texture structure 11 can be configured to reduce the stress of glass deformation.

The light-transparent deformation object 12 can be located in the space of the target texture structure 11 to cause the visual effect of the target texture structure 11 to disappear.

In embodiments of the present disclosure, the refractive index of the light-transparent deformation object and the refractive index of the glass can satisfy the same condition. Thus, when the light-transparent deformation object is located within the space of the target texture structure, the visible effect of the target texture structure can disappear. In some embodiments, the refractive index of the light-transparent deformation object and the refractive index of the glass satisfying the same condition can include the refractive index of the light-transparent deformation object being the same or substantially the same as the refractive index of the glass. In some embodiments of the present disclosure, a material of the light-transparent deformation object can be a transparent inorganic material, such as transparent adhesive, etc., which is not limited in the present disclosure and can be determined as needed.

In the glass of embodiments of the present disclosure, the first portion of the glass can include the target texture structure. The target texture structure can be configured to reduce the stress of glass deformation. Therefore, when the target texture structure is provided on the surface of a flexible screen, the target texture structure can protect the display screen from physical damages such as scratches and impacts that may occur during daily use and can also have a minimal impact on the flexible characteristics of the display screen. Thus, the design flexibility of the electronic device, including the flexible screen, and the user experience can be improved.

In embodiments of the present disclosure, as shown in FIG. 2, the target texture structure 11 includes a plurality of blind holes arranged in an array at the first portion 10. By providing a plurality of blind holes at the first portion 10, the deformation stress in the first portion 10 of the glass can be reduced. In some other embodiments of the present disclosure, as shown in FIG. 3, the target texture structure 11 includes a plurality of through-holes arranged in an array at the first portion 10. By providing a plurality of through-holes at the first portion 10, the deformation stress at the first portion 10 of the glass can be reduced. The difference between blind holes and through-holes is that the through-holes penetrate the glass, while the blind holes do not.

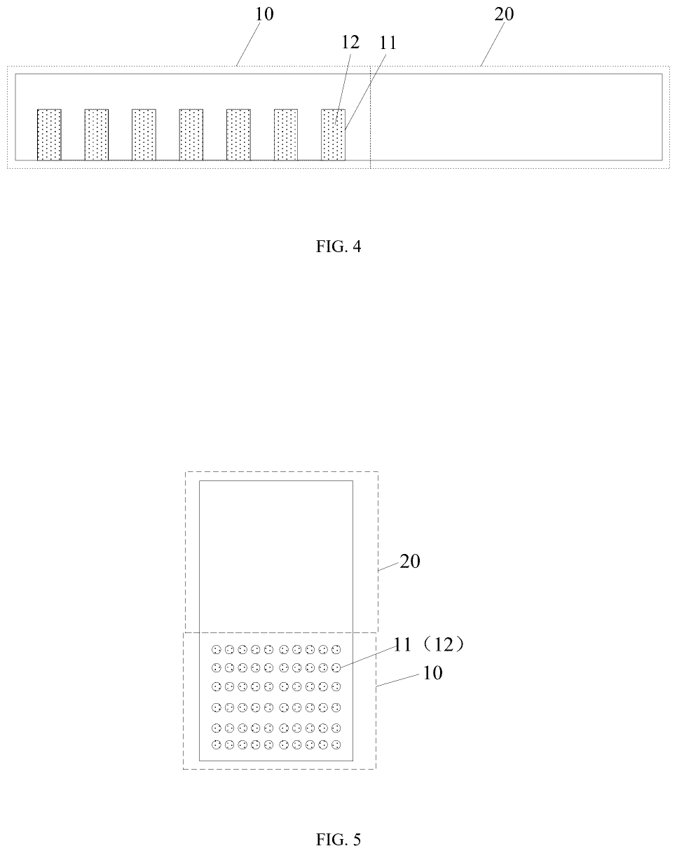

When the glass is provided on the surface of a flexible screen to form the electronic device, the electronic device can have different deformation requirements in different areas. For example, the electronic device can only require some parts to be bendable. Thus, in some embodiments, as shown in FIG. 4 to FIG. 7, the glass also includes a second portion 20. The second portion 20 can have a smaller deformation degree than the first portion 10. In some embodiments, the second portion 20 does not include a target texture structure. The target texture structure of the first portion 10 can cause the first portion to have a larger deformation degree than the second portion. In some embodiments, when the glass is used as a part of a bendable electronic device, the first portion can be located in the bendable area of the electronic device, and the second portion can be located in the non-bendable area.

In some embodiments, after the target texture structure reduces the deformation stress at the first portion, the deformation stress of the entire glass can be reduced. Therefore, when the glass includes the second portion, the target texture structure can also reduce the deformation stress of the glass.

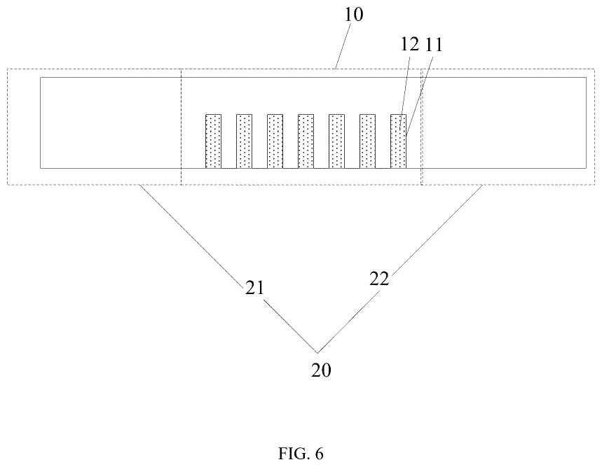

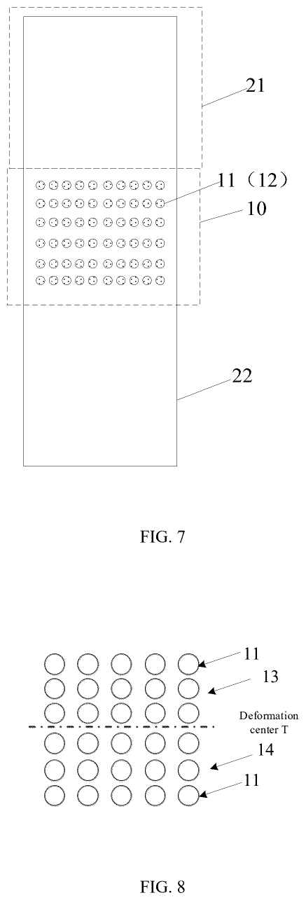

Based on the above embodiments, in embodiments of the present disclosure, as shown in FIG. 4 and FIG. 5, the first portion 10 and the second portion 20 are arranged side by side. That is, the second portion 20 is arranged on one side of the first portion 10 to allow the glass to adapt to a rollable and bendable electronic device. In some other embodiments of the present disclosure, as shown in FIG. 6 and FIG. 7, the second portion 20 includes a first sub-portion 21 and a second sub-portion 22. The first portion 10 is located between the first sub-portion 21 and the second sub-portion 22 to allow the glass to adapt to an inward-folding or outward-folding electronic device.

Based on any of the above embodiments, in embodiments of the present disclosure, a thickness of the first portion can be the same as a thickness of the second portion to ensure uniform thickness throughout the glass. In embodiments of the present disclosure, the thickness of the first portion can include at least one of a first thickness of the first portion, a first thickness of the light-transparent deformation object, a second thickness of the first portion, or a second thickness of the light-transparent deformation object.

In embodiments of the present disclosure, when the thickness of the first portion includes the first thickness of the first portion, as shown in FIG. 3, the first thickness of the first portion can be thickness H1 of the first portion when the target texture structure is the through-holes penetrating the first portion. As shown in FIG. 2, when the target texture structure is the blind holes not penetrating the first portion, the first thickness of the first portion is thickness H2 of the area where the non-target texture structure of the first portion is. When the thickness of the first portion includes the thickness of the light-transparent deformation object, the first thickness of the first portion can be the thickness of the light-transparent deformation object in the through-holes. As shown in FIG. 1, when the thickness of the first portion includes a combination of the second thickness of the first portion and the second thickness of the light-transparent deformation object, the first thickness of the first portion can be a sum of the thickness of the first portion (i.e., second thickness H3 of the first portion) and the thickness of the light-transparent deformation object in the blind holes (i.e., second thickness H4 of the light-transparent deformation object) at the area where the blind holes are.

In embodiments of the present disclosure, when the thickness of the first portion includes a combination of second thickness H3 of the first portion and second thickness H4 of the light-transparent deformation object, a ratio H3/(H3+H4) of second thickness H3 of the first portion to the sum of second thickness H3 of the first portion and second thickness H4 of the light-transparent deformation object can range from 0.4 to 0.7 to consider the protective strength and deformation performance, which is not limited in the present disclosure and should be determined as needed.

In embodiments of the present disclosure, second thickness H3 of the first portion can be less than 100 micrometers, and the sum of second thickness H3 of the first portion and second thickness H4 of the light-transparent deformation object can be greater than 100 micrometers, which are not limited in the present disclosure and shall be determined as needed.

In some embodiments, the depth of the space of the target texture structure can be related to the deformation degree. The thickness (or depth) of the target texture structure is not limited in the present disclosure and is determined according to the deformation requirement of the first portion.

For example, the target texture structure can be the blind holes at the first portion, and the first portion of embodiments of the present disclosure can be described below.

Based on any of the above embodiments, in embodiments of the present disclosure, as shown in FIG. 8, the first portion includes a deformation center T, a third sub-portion 13, and a fourth sub-portion 14 located on opposite sides of the deformation center T. In an implementation of embodiments of the present disclosure, the target texture structure 11 at the third sub-portion 13 and the target texture structures 11 at the fourth sub-portion 14 are arranged symmetrically about the deformation center T. In some embodiments, the target texture structure 11 at the third sub-portion 13 has a same layout pattern as the target texture structure 11 at the fourth sub-portion 14, and the layout pattern of the target texture structure 11 at the third sub-portion 13 and the layout pattern of the target texture structure 11 at the fourth sub-portion 14 can be centrally symmetric or axially symmetric about the deformation center T, which is not limited in the present disclosure. In some other embodiments of the present disclosure, the target texture structure at the third sub-portion and the target texture structures at the fourth sub-portion may not be arranged symmetrically about the deformation center, which is determined as needed.

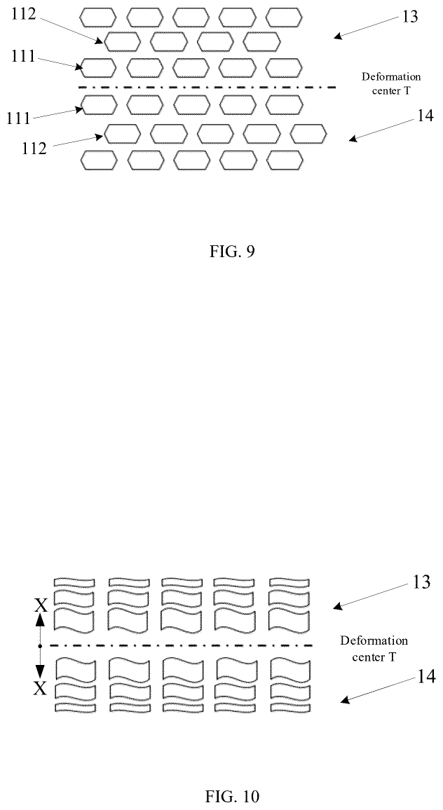

Based on the above embodiments, in embodiments of the present disclosure, as shown in FIG. 8, the target texture structure 11 has a matrix arrangement to allow the first portion to have a uniform deformation stress. In some other embodiments of the present disclosure, as shown in FIG. 9, the arrangement of the target texture structure 11 includes a direction perpendicular to the deformation center, a first arrangement row, and a second arrangement row that are staggered. The target texture structure 112 of the second arrangement row covers the gap between two neighboring target texture structures 111 of the first arrangement row. In some embodiments, the number of the target texture structures of the first arrangement row can be equal to the number of the target texture structures of the second arrangement row. In the fourth sub-portion 14 in FIG. 9, the number of the target texture structures of the first arrangement row is larger than the number of the target texture structures of the second arrangement row. In the fourth sub-portion 14 in FIG. 9, the number of the target texture structures of the first arrangement row is less than the number of the target texture structures of the second arrangement row, which is not limited in the present disclosure and should be determined as needed.

In embodiments of the present disclosure, as shown in FIGS. 8 to 10, the target texture structure can be a circular hole, an elliptical hole, a flag-shaped hole, or holes of other shapes, which is not limited in the present disclosure and should be determined according to the deformation stress requirements of the area where the target texture structure is located.

To facilitate the description, the first portion can be the bendable portion of the glass. The second portion can be the non-bendable portion of the glass.

During an actual bending process, different positions in the first portion at varying distances from the second portion (e.g., the boundaries of the first portion and the second portion) can have different deformation stresses. Therefore, in embodiments of the present disclosure, the target texture structures at different positions in the first portion can reduce the deformation stress of the area by different degrees. In embodiments of the present disclosure, when a target texture structure is farther from the second portion, the target texture structure can change the deformation stress of the area of the target texture structure at a greater degree. When a target texture structure is nearer to the second portion, the target texture structure can change the deformation stress of the area of the target texture structure to a smaller degree.

In embodiments of the present disclosure, the size of the target texture structure can gradually decrease along the direction away from the deformation center of the first portion. Thus, holes with different sizes can be provided to areas in the first portion with different deformation capabilities to further optimize the deformation performance of the first portion. In some embodiments of the present disclosure, the size of the target texture structure can be the diameter of the target texture structure.

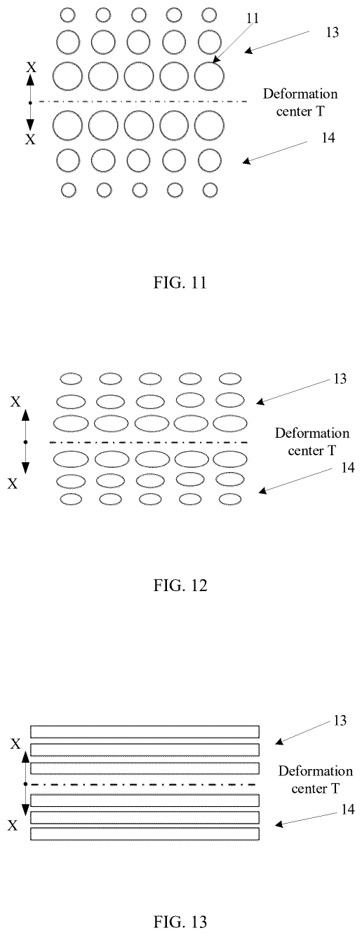

As shown in FIG. 11, in embodiments of the present disclosure, the target texture structure 11 is a circular hole. In embodiments of the preset disclosure, the sizes of the target texture structures 11 at the first portion gradually decrease along direction X away from the deformation center to allow the size of the target texture structure 11 at the area requiring the larger deformation capability at the first portion to be larger, and the size of the target texture structure 11 at the area requiring the smaller deformation capability at the first portion to be smaller. Then, the holes of different sizes can be provided to the areas with different deformation capabilities at the first portion to further optimize the deformation capability of the first portion. In some embodiments, the size of the target texture structure 11 can be the diameter of the target texture structure.

In some other embodiments of the present disclosure, as shown in FIG. 12, the target texture structure 11 is an elliptical hole. In embodiments of the present disclosure, the sizes of the target texture structure 11 at the first portion gradually decrease along direction X away from the deformation center. Thus, the size of the target texture structure 11 at the area requiring the larger deformation capability at the first portion can be larger, and the size of the target texture structure 11 at the area requiring the smaller deformation capability at the first portion can be smaller. Then, the holes of different sizes can be provided to the areas with different deformation capabilities at the first portion to further optimize the deformation capability of the first portion. In some embodiments, the size of the target texture structure 11 can be the major axis, minor axis, or a combination thereof of the target texture structure, which is not limited in the present disclosure and should be determined as needed.

In yet some other embodiments of the present disclosure, as shown in FIG. 10, the target texture structure 11 is a flag-shaped hole. In some embodiments, the sizes of the target texture structure 11 at the first portion gradually decrease along direction X away from the deformation center. Thus, the size of the target texture structure 11 at the area requiring the larger deformation capability at the first portion can be larger, and the size of the target texture structure 11 at the area requiring the smaller deformation capability at the first portion can be smaller. Then, the holes of different sizes can be provided to the areas with different deformation capabilities at the first portion to further optimize the deformation capability of the first portion. In some embodiments, the size of the target texture structure 11 can be the size of the target texture structure in first direction X. First direction X is perpendicular to the deformation center T of the first portion.

In the above embodiments, in the direction away from the deformation center of the first portion, the sizes of the target texture structures can gradually decrease, which is not limited to the present disclosure. As shown in FIG. 8 and FIG. 9, in some other embodiments, in the direction away from the deformation center of the first portion, the size of the target texture structure is fixed.

Additionally, in the above embodiments, in target texture structure rows in the direction away from the deformation center of the first portion, each target texture structure row can include a plurality of target texture structures, which is not limited in the present disclosure. In other embodiments of the present disclosure, each target texture structure row also includes only one target texture structure, as shown in FIG. 13, to simplify the manufacturing complexity of the first portion. Although FIG. 13 illustrates the top-view shape of the target texture structure as rectangular, which is not limited in the present disclosure. In other embodiments of the present disclosure, the top-view shape of the target texture structure can also be wavy or other shapes, which is determined as needed.

For example, in the above embodiments, the sizes of the target texture structures can gradually decrease in the direction away from the deformation center of the first portion, the target texture structures at different positions of the first portion can reduce the deformation stresses at the area at different degrees, which is not limited in the present disclosure. In some embodiments of the present disclosure, the sizes of the target texture structures can be the same, and the gaps between neighboring target texture structures in the direction away from the deformation center of the first portion can gradually increase, or the sizes of the target texture structures can be the same, and the depths of the neighboring target texture structures can gradually decrease in the direction away from the deformation center of the first portion, or the sizes of the target texture structures can be the same, and the texture patterns formed by the target texture structures can be different at different areas, to allow the target texture structures at different positions of the first portion to reduce the deformation capabilities of the areas at different degrees. Thus, a corresponding texture pattern can be provided for the stress adjustment degree of the area to optimize the adjustment performance of the target texture structures of the first portion.

In some embodiments of the present disclosure, the first portion can include a plurality of sub-deformation areas. The texture patterns formed by the target texture structures of the different sub-deformation areas can be different. For example, the first portion can include a first sub-deformation area and a second sub-deformation area. A distance between the second sub-deformation area and the deformation center of the first portion can be greater than the distance between the first sub-deformation area and the deformation center of the first portion. In some embodiments, the texture pattern formed by the target texture structure of the first sub-deformation area can be the first pattern. The texture pattern formed by the target texture structure of the second sub-deformation area can be the second pattern. The first pattern can be different from the second pattern. For example, the first pattern can be a rectangular pattern, and the second pattern can be a triangular pattern, which is not limited in the present disclosure, as long as the first pattern is different from the second pattern.

In some embodiments of the present disclosure, the first portion can include a third sub-portion and a fourth sub-portion on two opposite sides of the deformation center. The third sub-portion can include a plurality of sub-deformation areas. The fourth sub-portion can include a plurality of sub-deformation areas. The target texture patterns formed by the target texture structures in the different sub-deformation areas symmetrical to the deformation center of the first portion can be the same. Thus, the texture patterns corresponding to the sub-deformation areas having the same distances to the deformation center of the first portion can be the same. The stress adjustment degrees for the sub-deformation areas having the same distances to the deformation center of the first portion can be the same, which are not limited in the present disclosure and should be determined as needed.

In some other embodiments of the present disclosure, the deformation stresses of the glass can be reduced through a plurality of methods. For example, the glass can be simultaneously configured with at least two of:
the sizes of the target texture structures gradually decreasing in the direction away from the deformation center of the first portion;
the gaps between the neighboring target texture structures gradually increasing in the direction away from the deformation center of the first portion;
the depths of the neighboring target texture structures gradually decreasing in the direction away from the deformation center of the first portion; or
the texture patterns formed by the target texture structures of the different sub-deformation areas of the first portion being different.

Although the above embodiments are described by taking the target texture structures being blind holes as an example, the description can also be suitable when the target texture structures are through-holes, which is not limited to the present disclosure.

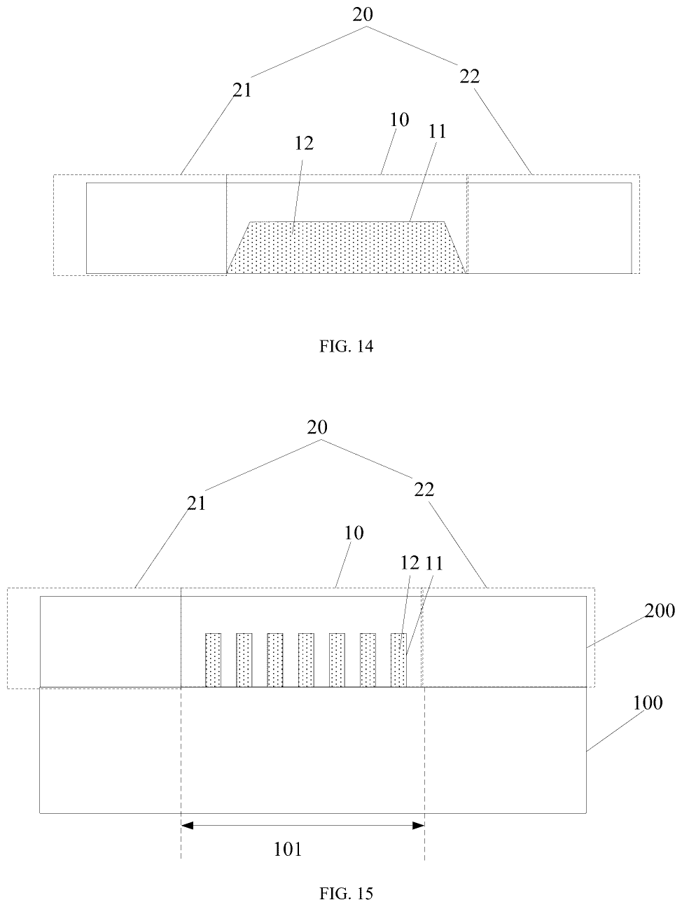

In addition to providing the plurality of holes at the first portion to reduce the deformation stress of the first portion of the glass, the stress of the first portion of the glass can be reduced in other methods. In some embodiments of the present disclosure, as shown in FIG. 14, the target texture structure is in a groove of the first portion. By providing the groove in the first portion, the deformation stress of the first portion of the glass can be reduced, which is not limited to the present disclosure and is determined as needed.

Based on any embodiment above, in embodiments of the present disclosure, the glass can further include a third portion. The third portion can be arranged between the first portion and the second portion. The deformation capability of the third portion can be greater than the deformation capability of the second portion and smaller than the deformation capability of the first portion. Thus, by providing the third portion between the first portion and the second portion, the transition from the deformation capability of the first portion to the deformation capability of the second portion can be realized to cause the deformation capabilities of different portions of the glass can gradually change, which is not limited in the present disclosure and should be determined as needed.

In addition, embodiments of the present disclosure further provide an electronic device. The electronic device can include the glass of any one of the embodiments above. In some embodiments, as shown in FIG. 15, the electronic device includes a deformation screen 100 and glass 200.

The screen 100 includes at least one first area 101.

The glass 200 covers the screen 100 and includes at least one first portion 10. The first portion 10 corresponds to the first area 101 of the screen 100. The light emitted by the screen 100 penetrates the glass 200.

The first portion 10 of the glass 200 includes a target texture structure 11 and a light-transparent deformation object 12 in the space of the target texture structure 11. The target texture structure 11 can be configured to reduce the deformation stress of the glass 200 deforming with the screen 100.

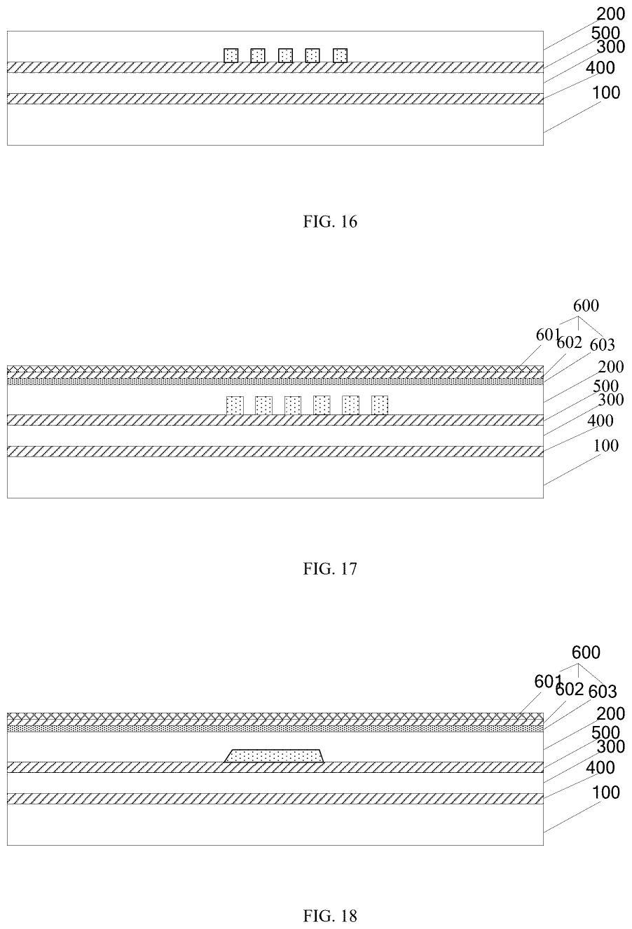

Based on the above embodiments, in embodiments of the present disclosure, as shown in FIG. 16, the electronic device further includes a transparent film 300 between the screen 100 and the glass 200 and configured to protect the screen 100 when the glass 200 is replaced or the glass 200 is not provided on the surface of the screen 100. In some embodiments, the transparent film can be a polyimide film, such as CPI (Colorless Polyimide) or PET (Polyethylene Terephthalate).

In some embodiments, the transparent film can be arranged between the display screen and the glass to shorten the distance between the glass and the display surface of the electronic device. Alternatively, the surface of the glass away from the display screen can be directly used as the display surface of the electronic device. When the user touches the surface of the electronic device, a good glass tactile feel can be ensured. Thus, when the glass has a small thickness, the surface of the electronic device can provide a good tactile feel to ensure that the surface of the electronic device has a good tactile feel while the thickness of the electronic device is reduced, which is beneficial for the electronic device to become thinner and lighter.

In embodiments of the present disclosure, as shown in FIG. 16, the transparent film 300 is fixedly connected to the screen 100 through a first adhesive layer 400. In some embodiments, the first adhesive layer 400 is a transparent adhesive layer. The transparent film 300 is fixedly connected to the glass 200 through a second adhesive layer 500. In some embodiments, the second adhesive layer 500 is a transparent adhesive layer, which is not limited in the present disclosure and should be determined as needed.

Based on any embodiment above, in embodiments of the present disclosure, as shown in FIG. 17 and FIG. 18, the electronic device further includes a functional layer 600 on a side of the glass 200 away from the screen 100. In some embodiments, the functional layer 600 includes a hardening layer 601 on the side of the glass 200 away from the screen 100 to reduce the light reflection of the display surface of the electronic device to improve the visual experience and to protect the display surface of the electronic device to prevent scratches and damage. In embodiments of the present disclosure, the hardening layer can be formed by adding hardening particles to the transparent adhesive layer. In some embodiments, the thickness of the hardening layer may not be greater than 10 micrometers, which is not limited in the present disclosure and should be determined as needed.

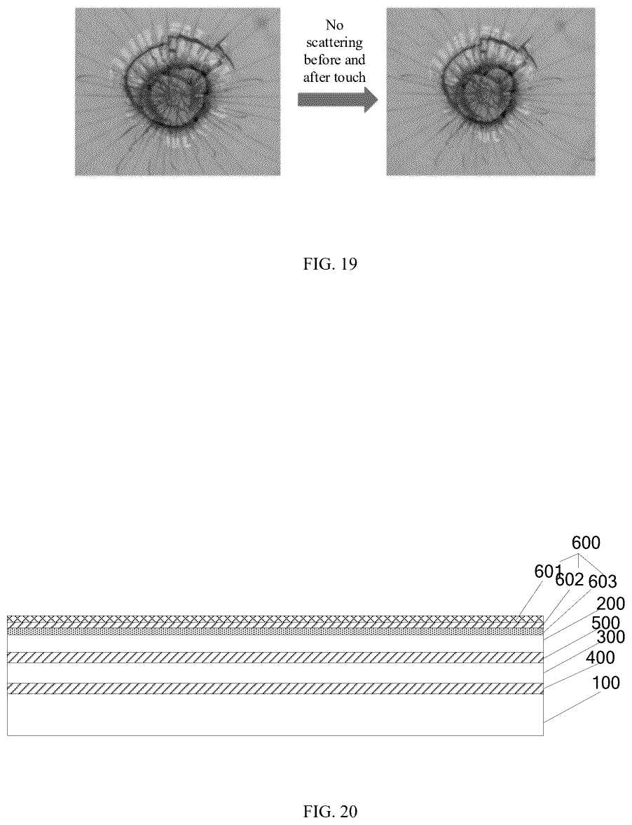

In some other embodiments of the present disclosure, as shown in FIG. 17 and FIG. 18, the functional year 600 includes an anti-shatter layer 602 on the side of the glass 200 away from the screen 100. Thus, when the glass is subjected to an external violent impact and shatters, glass fragments can be held in place to ensure that the fragments adhere to prevent the fragments from scattering to hurt the people around the electronic device. In some embodiments, the thickness of the anti-shatter layer may not be greater than 100 micrometers, which is not limited in the present disclosure and can be determined as needed. FIG. 19 illustrates an enlarged diagram showing the shattered area when the glass shatters after the glass is subjected to an external violent collision after the anti-shatter layer is provided on the surface of the glass. As shown in FIG. 19, the anti-shatter layer provided on the surface of the glass can hold the fragments when the glass shatters when the glass is subjected to the external violent collision to fix the glass fragments in a small area. Moreover, when the glass shatters, the shattered area of the glass may not change after being contacted by the user to prevent the fragments from scattering to hurt the user.

In yet some other embodiments of the present disclosure, as shown in FIG. 17 and FIG. 18, the functional layer 600 includes a hardening layer 601 formed on the side of the glass 200 away from the display screen 100, and an anti-shatter layer 602 arranged between the glass 200 and the hardening layer 601. The hardening layer 601 can be configured to reduce light reflection on the display surface of the electronic device, improve visual experience, and protect the display surface of the electronic device to prevent scratches and damage. The anti-shatter layer 602 can be configured to hold glass fragments in place when the glass shatters to ensure fragments are adhered to prevent scattering to hurt people around the electronic device.

In embodiments of the present disclosure, as shown in FIG. 17 and FIG. 18, the functional layer 600 further includes a buffer layer 603 arranged between the anti-shatter layer 602 and the glass 200. The buffer layer 603 can be configured to adjust the stress at the contact interface between the anti-shatter layer 602 and the glass 200, enhance the bonding force between the anti-shatter layer 602 and the glass 200, and reduce the risk of the anti-shatter layer 602 peeling off from the glass 200 surface. In embodiments of the present disclosure, the thickness of the buffer layer may not be greater than 5 micrometers, which is not limited to the present disclosure, and should be determined as needed.

In embodiments of the present disclosure, the anti-shatter layer can be directly arranged on the glass surface to improve the collision resistance of the glass. Then, when the thickness of the glass is thin, the glass can also provide good protection. Thus, in some other embodiments of the present disclosure, as shown in FIG. 20, the target texture structure may not be provided at the first portion, but the entire glass can be thinned to reduce the deformation stress of the glass. In some embodiments, when the glass has a uniform thickness, and the thickness of the glass is smaller than 100 micrometers, which is not limited in the present disclosure and should be determined as needed.

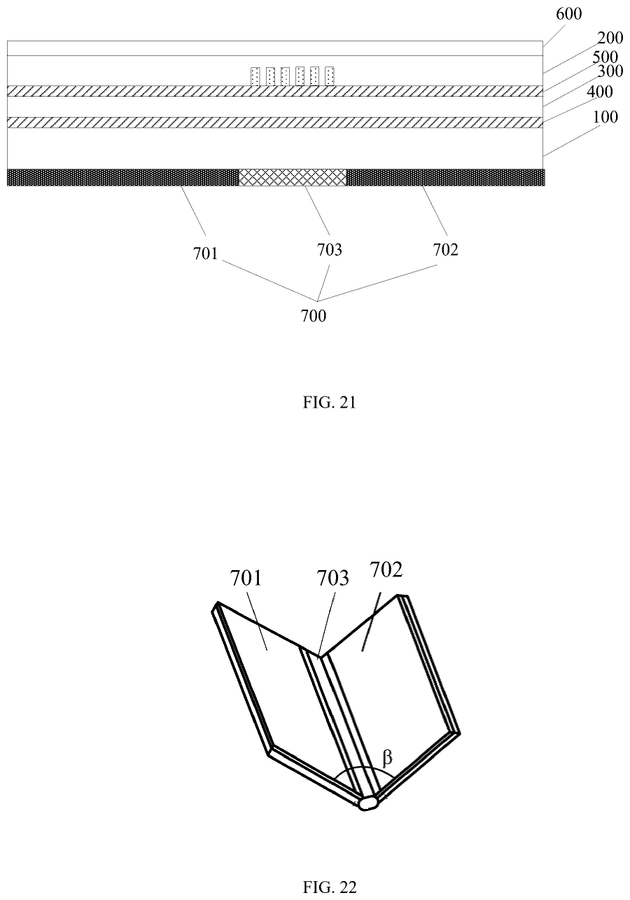

Based on any embodiment above, in embodiments of the present disclosure, the electronic device can be a foldable electronic device. In some embodiments, as shown in FIG. 21 and FIG. 22, the electronic device further includes a device body 700. The device body 700 includes a first body 701, a second body 702, and a connection member connecting the first body 701 and the second body 702. The second body 702 can rotate relative to the first body 701. In some embodiments, the screen can further include a second area. The first body 701 and the second body 702 can support the second area to cause the second area of the screen to be in an unfolded state. The connection member 703 can correspond to the first area of the screen 100. Thus, the first area of the screen 100 can deform as the second body and the first body rotate relatively.

In embodiments of the present disclosure, the electronic device can be an inward-folding electronic device. That is, if the electronic device is in a folded-in-half state, the display surface of the electronic device can be attached. In some other embodiments of the present disclosure, the electronic device can be an outward-folding electronic device. That is, when the device is in a folded-in-half state, the non-display surface of the electronic device can be attached.

In the above embodiments, when the electronic device is an inward-folding device, the performance requirement for the side of the glass facing away from the screen can be higher than the performance requirement of the side of the glass facing the screen. Thus, in embodiments of the present disclosure, the target texture structure can be arranged on the side of the glass away from the screen to cause the deformation capability of the side of the glass away from the screen to be greater than the deformation capability of the side of the glass facing the screen. When the electronic device is an outward-folding device, the performance requirement for the side of the glass facing away from the screen can be lower than the performance requirement of the side of the glass facing the screen. Thus, in embodiments of the present disclosure, the target texture structure can be arranged on the side of the glass facing the screen to cause the deformation capability of the side of the glass facing the screen to be greater than the deformation capability of the side of the glass away from the screen. The electronic device can be inwardly or outwardly folded. The target texture structure can be only arranged on the side of the glass facing the screen, only on the side of the glass away from the screen, or simultaneously on the side of the glass facing and the side of the glass away from the screen, which is not limited in the present disclosure and should be determined as needed.

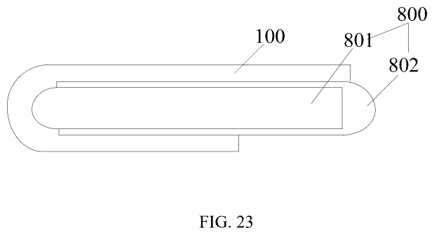

In some other embodiments of the present disclosure, the electronic device can be a rollable screen electronic device, such as a slide-out electronic device. In some embodiments, as shown in FIG. 23, the electronic device further includes a support member 800 arranged on a non-display side of the screen 100. The support member 800 includes a first support member 801 and a second support member 802. The second support member 802 can slide relative to the first support member 801. An end of the screen 100 is fixedly connected to an end of the second support member 802. The display surface of the screen 100 on the first side of the electronic device can change as the second support member 802 slides relatively to the first support member 801. Thus, the display area of the screen 100 on the first side of the electronic device can be adjusted. In some other embodiments, when the electronic device is a rollable screen electronic device, the electronic device can also be a scroll-style electronic device, which is not limited in the present disclosure and should be determined as needed.

In summary, in the glass and the electronic device, including the glass of embodiments of the present disclosure, the first portion of the glass can include the target texture structures. The target texture structures can be configured to reduce the deformation stress of the glass. Thus, when the glass is provided on the surface of the flexible screen, the glass can protect the screen from resisting physical damage such as scratches and collisions in daily use. The glass can also have a small impact on the flexibility characteristics. Thus, the design flexibility of the electronic device, including the flexible screen, and the user experience can be improved.

Various embodiments in the present specification are described in a progressive, parallel, or progressive and parallel manner. Each embodiment focuses on differences from other embodiments. Similar or identical parts between embodiments can be cross-referenced. For the apparatus disclosed in embodiments of the present disclosure, since the apparatus corresponds to the method of embodiments of the present disclosure, the description can be simple. The relevant parts can be relatively simple. For the relevant details, reference can be made to the description of the method.

The above descriptions of embodiments of the present disclosure can enable those skilled in the art to implement or use the present disclosure. Various modifications to these embodiments are apparent to those skilled in the art. The general principles defined here can be realized in other embodiments without departing from the spirit or scope of the present disclosure. Thus, the present disclosure is not limited to embodiments of the present disclosure but should conform to the broadest scope consistent with the principles and novel features of the present disclosure.

What is claimed is:

1. A glass comprising a first portion, including:
a target texture structure configured to reduce deformation stress of the glass; and
a light-transparent deformation object arranged in a space of the target texture structure to cause a visual effect of the target texture structure to disappear.

2. The glass according to claim 1, further comprising a second portion, wherein:
a deformability of the second portion is less than a deformability of the first portion; and
the target texture structure causes the deformability of the first portion to be greater than the deformability of the second portion.

3. The glass according to claim 2, wherein:
a thickness of the first portion is the same as a thickness of the second portion; and
the thickness of the first portion includes at least one of:
a first thickness of the first portion;
a first thickness of the light-transparent deformation object; or
a combination of a second thickness of the first portion and a second thickness of the light-transparent deformation object.

4. The glass according to claim 1, wherein the target texture structure includes a plurality of blind holes arranged in an array and located at the first portion.

5. The glass according to claim 1, wherein the target texture structure includes a plurality of through-holes arranged in an array and located at the first portion.

6. The glass according to claim 5, wherein a depth of the space of the target texture structure is related to a deformation degree.

7. The glass according to claim 2, wherein the second portion includes a first sub-portion and a second sub-portion, and the first portion is arranged between the first sub-portion and the second sub-portion.

8. An electronic device comprising:
a deformation screen including at least one first area; and
glass covering the screen and including at least one first portion, the first portion corresponding to the first area of the screen, and light emitted from the screen penetrating the glass;
wherein the first portion of the glass includes a target texture structure and a light-transparent deformation object arranged in a space of the target texture structure, and the target texture structure is configured to reduce deformation stress of the glass as the screen deforms.

9. The electronic device according to claim 8, further comprising a device body, including:
a first body, a second body, and a connection member connecting the first body and the second body, the second body being able to rotate relative to the first body;
wherein:
the screen further includes a second area;
the first body and the second body support the second area of the screen to cause the second area of the screen to be in an unfolded state; and
the connection member corresponds to the first area of the screen to cause the first area of the screen to deform as the second body rotates relative to the first body.

10. The electronic device according to claim 8, further comprising a support member arranged on a non-display side of the screen and including a first support member and a second support member, wherein:
the second support member is able to slide relative to the first support member;
an end of the screen is fixedly connected to an end of the second support member; and
a display area of the screen on a first side of the electronic device changes as the second support member slides relative to the first support member.

11. The electronic device according to claim 8, wherein:
the glass further includes a second portion;
a deformability of the second portion is less than a deformability of the first portion; and
the target texture structure causes the deformability of the first portion to be greater than the deformability of the second portion.

12. The electronic device according to claim 11, wherein:
a thickness of the first portion is the same as a thickness of the second portion; and
the thickness of the first portion includes at least one of:
a first thickness of the first portion;
a first thickness of the light-transparent deformation object; or
a combination of a second thickness of the first portion and a second thickness of the light-transparent deformation object.

13. The electronic device according to claim 8, wherein the target texture structure includes a plurality of blind holes arranged in an array and located at the first portion.

14. The electronic device according to claim 8, wherein the target texture structure includes a plurality of through-holes arranged in an array and located at the first portion.

15. The electronic device according to claim 14, wherein a depth of the space of the target texture structure is related to a deformation degree.

16. The electronic device according to claim 11, wherein the second portion includes a first sub-portion and a second sub-portion, and the first portion is arranged between the first sub-portion and the second sub-portion.

17. The electronic device according to claim 8, wherein:
the electronic device is a foldable device including a flexible screen; and
the first portion of the glass having the target texture structure corresponds to a deformation area of the flexible screen.

18. The electronic device according to claim 8, wherein:
the electronic device is a rollable device including a flexible screen; and
the first portion of the glass having the target texture structure corresponds to a deformation area of the flexible screen.
